(19) United States
(12) Patent Application Publication
(10) Pub. No.: US 2007/0295357 A1
(43) Pub. Date: Dec. 27, 2007

(54) REMOVING METAL USING AN OXIDIZING CHEMISTRY

(76) Inventors: Michael Luke Lovejoy, Austin, TX (US); Ross E. Noble, Austin, TX (US); Mohamad Jahanbani, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/426,755

(22) Filed: Jun. 27, 2006

(51) Int. Cl. C23G 1/00; H01L 21/306

(52) U.S. Cl. 134/2; 156/345.11

(57) ABSTRACT

A method of removing a metal includes exposing at least a portion of a metal-to-metal removal chemistry, wherein the metal removal chemistry comprises a chlorine-rich superoxidizer. In one embodiment, the metal being removed is a metal, such as a noble metal, that did not react with the semiconductor device during a salicidation process. In one embodiment, the chlorine-rich superoxidizer is formed by mixing hydrochloric acid in gas form with hydrogen peroxide and sulfuric acid. The metal can be exposed to the chlorine-rich superoxidizer in various ways, such as through an immersion or spray process.

### FIELD OF THE INVENTION

This disclosure relates generally to forming semiconductor devices, and more specifically, to removing a metal using an oxidizing chemistry.

### BACKGROUND

As semiconductor device dimensions decrease, silicides including noble metals, such as platinum (Pt), are being used. When forming a silicide including a noble metal, a noble metal is deposited over a semiconductor device, an anneal is performed to react the noble metal with silicon, and any unreacted noble metal is removed. However, most current chemistries do not remove all of the unreacted noble metal, which can cause leakage problems. One solution is to use Aqua Regia, which includes 3 parts HCl in liquid form and 1 part HNO₃ in liquid form, since this chemistry completely removes Pt. However, when removing the Pt, Aqua Regia undesirably roughens the surface of the semiconductor device, which causes leakage problems. In addition, Aqua Regia outgasses chlorine over time and after about 6 to 7 hours, the chemistry being used needs to be thrown away and replaced. The outgassing reduces the effectiveness of Aqua Regia. In addition, the frequent need to replace Aqua Regia is costly and time consuming. Therefore, a need exists for a chemistry and process for removing unreacted noble metals, such as Pt, that does not cause leakage problems and does not outgas chlorine.

### BRIEF DESCRIPTION OF THE DRAWINGS

The present invention is illustrated by way of example and is not limited by the accompanying figures, in which like references indicate similar elements.

FIG. 1 illustrates an immersion tool for removing unreacted metals in accordance with various embodiments;

FIG. 2 illustrates another immersion tool for removing unreacted metals in accordance with another embodiment;

FIG. 3 illustrates a spray tool for removing unreacted metals in accordance with another embodiment;

FIG. 4 illustrates another spray tool for removing unreacted metals in accordance with another embodiment;

FIG. 5 illustrates another spray tool for removing unreacted metals in accordance with another embodiment;

FIG. 6 illustrates another spray tool for removing unreacted metals in accordance with another embodiment;

FIG. 7 illustrates the a cross-section of a portion of a semiconductor substrate after forming a metal layer in accordance with an embodiment;

FIG. 8 illustrates the semiconductor substrate of FIG. 7 during an anneal process in accordance with an embodiment; and

FIG. 9 illustrates the semiconductor substrate of FIG. 7 after removing portions of the metal layer (e.g., the unreacted metal portions) in accordance with an embodiment.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

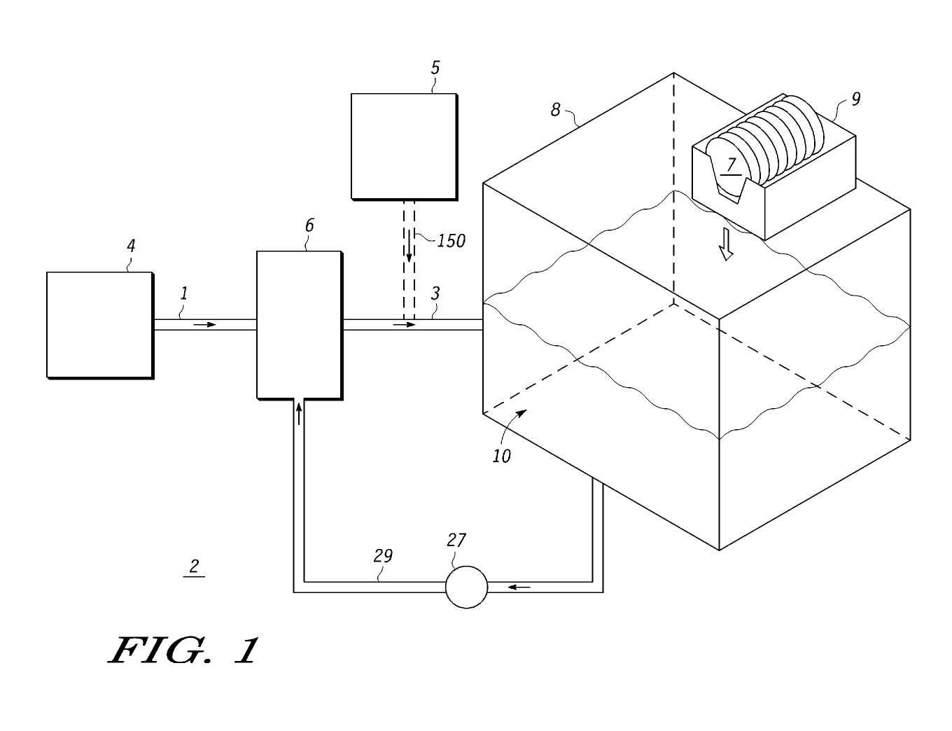

FIG. 1 illustrates an immersion tool 2 having a gas including chlorine source 4 or 5, a filter 6, and a (immersion) tank 8 with a solution or chemical bath 10 in which cassette 9 is immersed. The cassette 9 includes at least one semiconductor wafer 7, which may be a semiconductor wafer at any stage of processing during a semiconductor manufacturing process. For example, as will be understood after further explanation, the semiconductor wafer may have unreacted noble metal on its surface that is removed during the immersion process that uses the immersion tool 2. The cassette 9 may include any number of semiconductor wafers 7, such as one or more semiconductor wafers.

The gas including chlorine source 4 or 5 can be any chemistry that will create a soluble free chloride, such as HCl gas. As shown in FIG. 1, the gas including chlorine source 4 is located before the filter 6 and hence, the gas including chlorine may pass through tubing or pipe 1 to the filter 6. Also shown in FIG. 1, the gas including chlorine source 5 is located after the filter 6, in another embodiment; in this embodiment the gas, including chlorine does not pass through the filter 6. The filter 6 is coupled to the tank 8 via tubing or pipe 3. In the embodiment where the gas including chlorine source 4 is located before the filter 6, the gas including chlorine travels through tubing 1, the filter 6, and tubing or pipe 3 to the tank 8. In the embodiment where the gas including chlorine source 5 is located after the filter 6, the gas including chlorine source 5 is coupled to the tubing 3, through which the gas including chlorine will travel into the tank 8. Regardless of where the gas including chlorine source 4 or 5 is located, the gas including chlorine from the gas including chlorine source 4 or 5 is in a gas phase, not a liquid phase.

The tank 8 includes the solution 10. In one embodiment, the solution 10 includes a superoxidizer. The superoxidizer may be one or more chemicals. For example, the superoxidizer may be peroxymonosulfuric acid, which is commonly referred to as Piranha or caro acid in the semiconductor industry. Piranha includes two chemicals. The first is hydrogen peroxide (H₂O₂), and the second chemical is sulfuric acid (H₂SO₄). In another embodiment, the superoxidizer may be only one chemical, such as nitric acid (HNO₃) (fuming or concentrated) or 50 weight percent of hydrogen peroxide. Other suitable superoxidizers can be used. Superoxidizers have high enough oxidizing powers to oxidize noble metals. Noble metals are metals that are resistant to corrosion or oxidation. Examples of noble metals include platinum (Pt), gold (Au), silver (Ag), palladium (Pd), copper (Cu), the like, alloys including the above metals, and combinations of the above. In one embodiment the noble metal alloy is NiPt, with approximately 5 percent of Pt. This process can also be successfully used on non-noble metal silicide, including but not limited to CoSi, NiSi, and TiSi.

After the gas including chlorine is injected or flown into the tank 8 from the gas including chlorine source 4 or 5, the solution 10 includes the gas including chlorine. After the solution 10 includes the gas including chlorine, the cassette 9 is immersed into the solution 10. As will be further explained below, when the solution 10 includes the gas including chlorine, the solution 10 is a metal removal chemistry, such as a noble metal removal chemistry that removes metals, such as noble metals, from the semiconductor wafers. The metal removal chemistry is a chlorine-rich superoxidizer. The chlorine gas may be continuously flown into the solution 10 while the cassette 9 is in the tank 8. Also, while the cassette 9 is immersed in the solution 10, the solution 10 may be filtered to remove impurities. The filtration can occur by recirculating the solution through the filter 6. During recirculation, the solution 10 travels from the tank 8 through the tubing or pipe 29, which is assisted by a pump 27, to the filter 6 and through the tubing 3 to the tank 8.

If the solution 10 includes H₂O₂, H₂O₂ may be added to the solution 10 so that the H₂O₂ is replenished since H₂O₂ may be depleted over time. The H₂O₂ can be added directly into the solution 10 through a tubing or pipe that couples an H₂O₂ source to the tank 8.

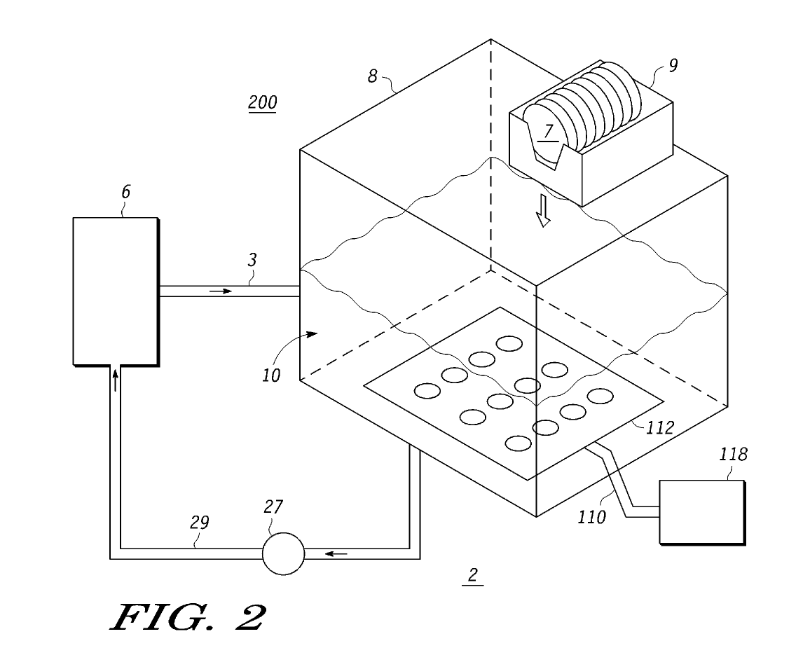

FIG. 2 illustrates another embodiment of an immersion tool 200 than can be used to remove metal. Like FIG. 1, the immersion tool 200 includes the filter 6, the tubings 3 and 29, the pump 27, the tank 8, the solution 10, and the cassette 9 with the semiconductor wafer(s) 7. In the embodiment illustrated in FIG. 2, the gas including chlorine is bubbled or diffused into the solution 10 through the bubbler or diffusion plate 112 that is coupled to the gas including chlorine source 118 via the tubing or pipe 110. Although not shown in FIGS. 1 or 2, in other embodiments the gas including chlorine can be injected directly into the tank 8 through an injection nozzle.

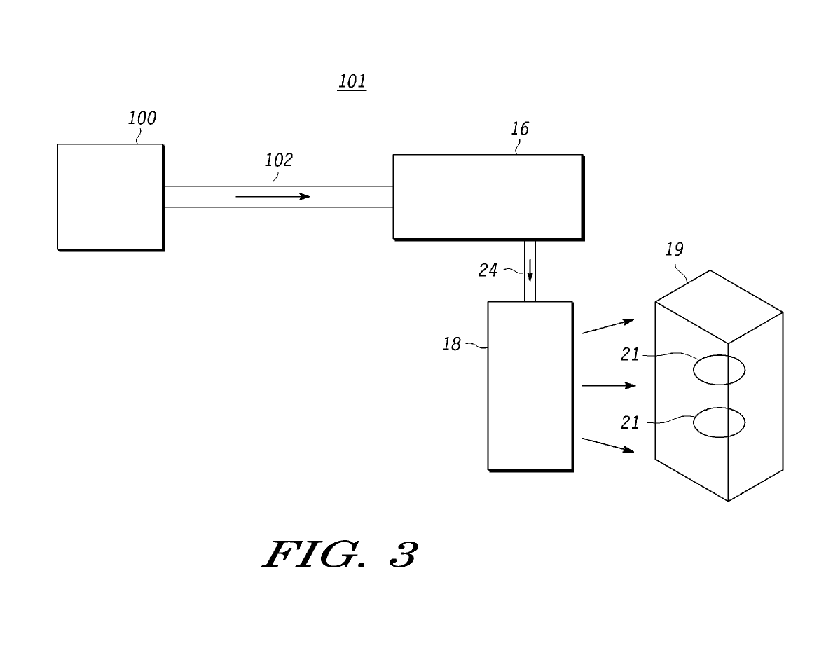

FIG. 3 illustrates an embodiment using a spray tool (or spray/spin tool) 101. The spray tool 101 includes a chemistry source 100, a chemical manifold 16, and a spray bar 18. The chemistry source 100 is coupled to the chemical manifold 16 via tubing or pipe 102 and the chemical manifold is coupled to the spray bar 18, in one embodiment via tubing or pipe 24. In another embodiment (not shown), the chemical manifold is directly connected to the spray bar 18. The chemistry source 100 includes the superoxidizer and the gas including chlorine that are mixed together to form the noble metal removal chemistry. For example, the chemistry source 100 may include Piranha and HCl gas. To form the noble metal removal chemistry, a gas including chlorine combines with a superoxidizer, such as Piranha. For example, a process similar to that shown in FIG. 1 can be used to form the noble metal removal chemistry that is stored in the chemistry source 100. The noble metal removal chemistry travels from the chemistry source 100 via the tubing 102 to the chemical manifold 16 where the noble metal removal chemistry may be combined with other chemicals (not shown) that are coupled to the chemical manifold 16. If no other chemicals are to be mixed with the noble metal removal chemistry, then the chemical manifold 16 may not be present.

After traveling through the chemical manifold 16, if present, the noble metal removal chemistry (which may be mixed with other chemicals) travels, in one embodiment through tubing or pipe 24 to the spray bar 18. The spray bar 18 sprays the noble metal removal chemistry (which may be mixed with other chemicals) onto at least one semiconductor wafer 21 that is within the cassette 19. The semiconductor wafers 21 are similar to the semiconductor wafers 7 in FIGS. 1 and 2 and the cassette 19 is similar to the cassette 9 in FIGS. 1 and 2. As shown in FIG. 3, the spray bar 18 sprays the semiconductor wafers 21 so the liquid is sheered across the front side and backside of the semiconductor wafers 21. The method shown in FIG. 3 is one example of a batch spray. However, any other batch spray process may be used. In addition, a single wafer spray process may be used. For example, in a single wafer spray process, a nozzle may dispense liquid onto the top surface of a semiconductor wafer, which lies underneath the nozzle. In addition, in a single wafer spray process a single wafer chuck may be used instead of the cassette 19.

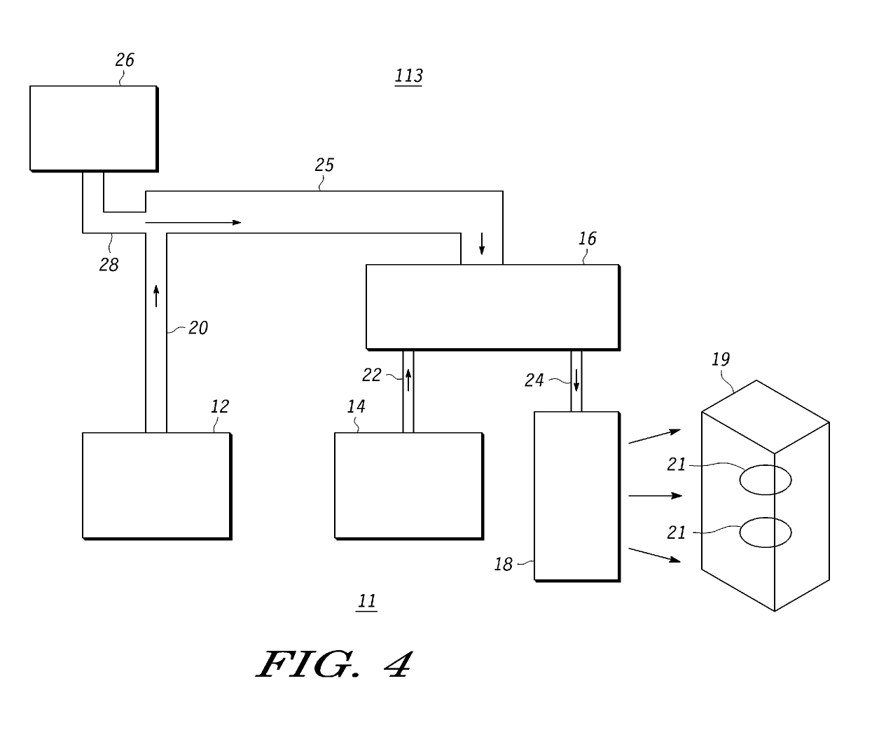

FIG. 4 illustrates another embodiment of a spray tool 113. In this embodiment, the spray tool 113 includes a gas including chlorine source 26, an oxidizer source 12, and an oxidizing acid source 14. In one embodiment, the oxidizer (e.g., H₂O₂) from the oxidizer source 12 and the oxidizing acid (e.g., H₂SO₄) from the oxidizing acid source 14 later combines to form the superoxidizer. In another embodiment, only the oxidizer or the oxidizing acid forms the superoxidizer. The gas including chlorine that is stored in the gas including chlorine source 26, in one embodiment, is HCl gas. The spray tool 113 also includes a chemical manifold 16 and a spray bar 18, which can be the same as the chemical manifold 16 and the spray bar 18 in other embodiments. Similar to other embodiments, is the cassette 19 that includes the semiconductor wafers 21.

The gas including chlorine is injected into tubing or pipe 28 and the oxidizer is injected from the oxidizer source 12 into the tubing or pipe 20. The gas including chlorine and the oxidizer mix in mixing tubing or pipe 25. The combination of the gas including chlorine and the oxidizer enter the chemical manifold 16, where the combination mixes with the oxidizing acid, which travels from the oxidizing acid source 14 to the chemical manifold via the tubing or pipe 22, to form a noble metal removal chemistry. Although not shown, the noble metal removal chemistry may mix with other chemical sources, which may or may not become part of the noble metal removal chemistry, in the chemical manifold 16. The noble metal removal chemistry travels from the chemical manifold 16 to the spray bar 18, in one embodiment via the tubing or the pipe 24. In another embodiment (not shown), the chemical manifold is directly connected to the spray bar 18, so the noble metal removal chemistry travels from the chemical manifold 16 directly into the spray bar 18. Similar to FIG. 3, the spray bar 18 is one example of a batch process and any other batch process or any single wafer spray process can be used instead.

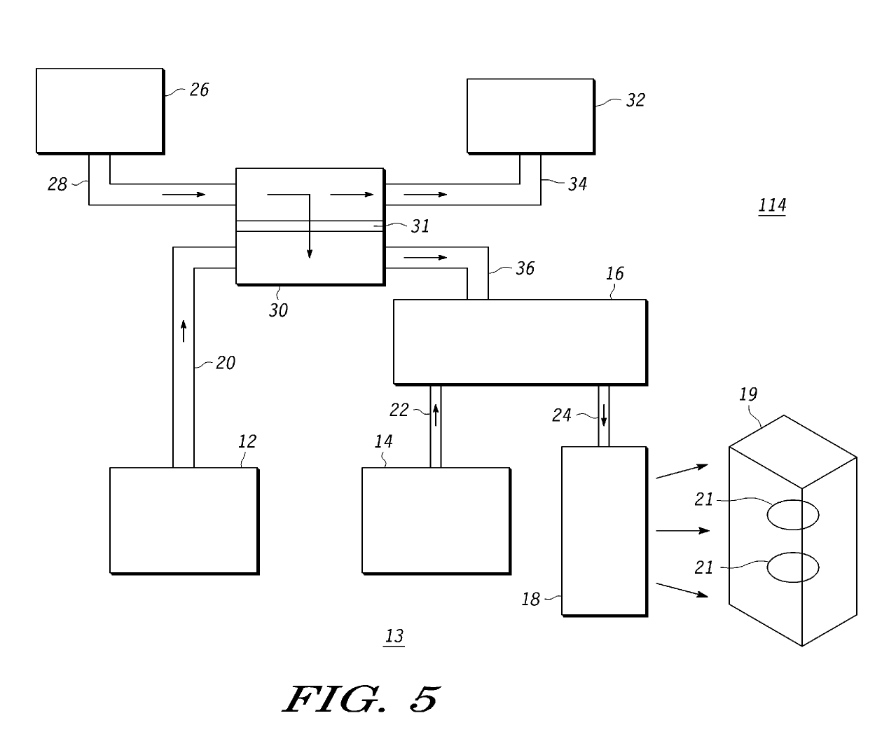

FIG. 5 illustrates an embodiment of a spray tool 114. The spray tool 114 is similar to the spray tool 113 in FIG. 4. However, the spray tool 114 further includes a contactor 30 with a semi-permeable membrane 31. When the gas including chlorine travels through the tubing 28 it travels into the contactor 30. In the contactor 30, the chlorine from the gas including chlorine diffuses across the semi-permeable membrane 31 into the oxidizer or more specifically the water portion of the oxidizer to form a chlorine-rich oxidizer. The semi-permeable membrane may be any suitable material that allows negative ions, such as chlorine, to diffuse into the oxidizer. In one embodiment, the semi-permeable membrane is polypropylene.

After the chlorine diffuses into the oxidizer, the chlorine-rich oxidizer travels from the contactor 30 to the chemical manifold 16 via the tubing or pipe 36. Any portion of the gas including chlorine that does not include chlorine (e.g., hydrogen if the gas including chlorine is HCl) travels through tubing or pipe 34 to the exhaust 32. In the chemical manifold 16, the chlorine-rich oxidizer and the oxidizing acid (which travels from the oxidizing acid source to the chemical manifold via the tubing 22) are combined. If the chlorine-rich oxidizer is chlorine-rich hydrogen peroxide and the oxidizing acid is H₂SO₄, the mixtures formed in the chemical manifold includes H₂SO₅+H₂O+Cl⁽⁻⁾+H₂O₂. This mixture is the noble metal removal chemistry in this embodiment.

As in previous embodiments, the chemical manifold 16 can be coupled to the spray bar 18 via the tubing 24 or in an embodiment not shown it is directly connected to the spray bar 18. The spray bar 18 disperses the noble metal removal chemistry so that it contacts the semiconductor wafers 21 that are in the cassette 19. As in previous embodiments, an example of a batch spray process is illustrated but any other batch process or any single wafer process may be used.

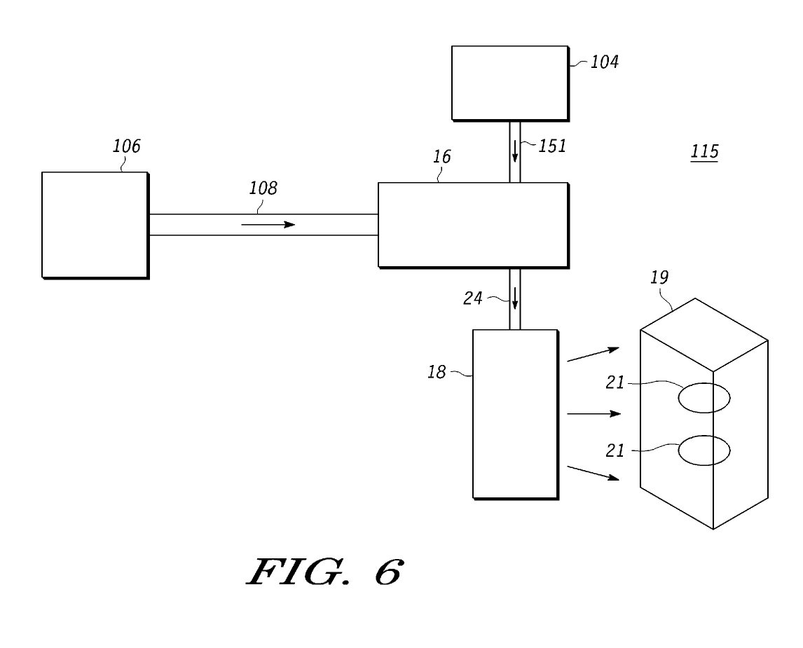

FIG. 6 illustrates an embodiment of a spray tool 115 where a chemical (e.g., H₂O₂ if the superoxidizer is Piranha) that will later combine with at least another chemical to form a superoxidizer is combined with the gas including chlorine (e.g., HCl gas) in a combined source 106. The combined chemistry travels from the combined source 106 via tubing or pipe 108 to the chemical manifold 16, where it mixes with other portions of the superoxidizer (and possibly other chemicals (not shown)). In the embodiment where the superoxidizer is Piranha, the combined chemistry (HCl and H₂O₂) is combined with H₂SO₄ in the chemical manifold 16 that is supplied from source 104 via tubing or pipe 151.

After being formed in the chemical manifold 16, the noble metal removal chemistry, which in one embodiment is Piranha and dissolved HCl gas, travels to the spray bar 18. In the embodiment illustrated, the chemical manifold 16 is coupled to the spray bar 18 via the tubing or pipe 24. In another embodiment, the chemical manifold 16 is directly connected to the spray bar 18 so the tubing 24 is not present. As in the other illustrated embodiments, the spray bar 18 sprays the noble metal removal chemistry onto the semiconductor wafer(s) 21 in the cassette 19. The illustrated embodiment is one example of a batch process. Other batch spray processes or single wafer spray processes can be used.

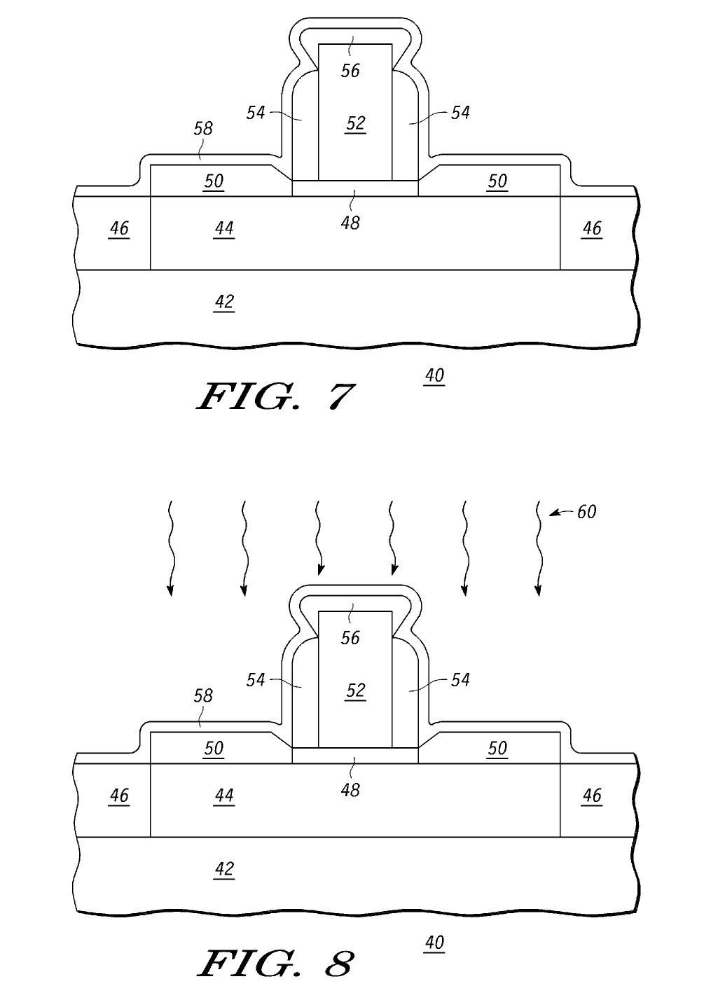

FIG. 7 illustrates a cross-section of a portion of a workpiece 40, which in the embodiment shown is a semiconductor device. The semiconductor device 40 illustrated uses a silicon-on-insulator (SOI) substrate and includes a buried oxide (BOX) layer 42 and an active layer 44 overlying the BOX layer. The active layer 44 may include silicon or any other suitable semiconductor material. Formed in the active layer 44 are isolation regions 46, which are formed in one embodiment using a shallow trench isolation (STI) process. The semiconductor device 40 may include any other suitable substrate such as a monocrystalline silicon substrate. A gate dielectric 48 is formed over the active layer 44 using conventional processing. The gate dielectric 48 can be any suitable material such as silicon dioxide or a dielectric having a high dielectric constant. (A high dielectric constant is one that is great greater than the dielectric constant of silicon dioxide.) Also formed over the active layer are raised source/drain regions 50, which are formed using conventional processing. Alternatively, the source/drain regions can be formed within the active layer 44. A gate electrode 52 is formed over the gate dielectric 48 and may be any suitable material such as polysilicon or a metal gate material. Adjacent the gate dielectric 48, spacers 54 are formed using any known processing. In one embodiment, the spacers 54 include an L-shaped oxide spacer and an adjacent nitride spacer. If the gate electrode 52, does not include silicon, a cap including silicon 56 is formed over the gate electrode 52 so that a silicide can be formed over the gate electrode 52. If the gate electrode 52 includes silicon, the cap including silicon 56 may not be formed since a silicide can be formed using the silicon from the gate electrode 52. The cap including silicon 56 may be polysilicon and can be formed by depositing a layer including silicon and later etching the silicon using any conventional etch process. A metal layer 58 is formed over the semiconductor device 40. The metal layer 58 can be any metal desirable to be used to form a silicide, such as Pt, another noble metal, transition metals, lanthanides, and actinides. The metal layer 58 can be formed by any suitable process, such as a deposition process (e.g., chemical vapor deposition, atomic layer deposition, the like, and combinations of the above.)

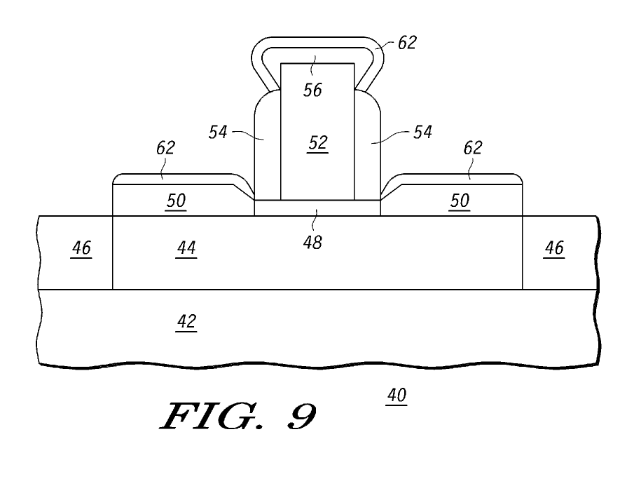

After forming the metal layer 58, an anneal 60 is performed as illustrated in FIG. 8. Any conventional anneal 60 can be used, such as a rapid thermal anneal (RTA). During the anneal the metal layer 58 reacts with silicon in the areas where the metal layer 58 is in contact with materials that include silicon (i.e., the cap including silicon 56 (or the gate electrode 52 if the cap including silicon 56 is not present) and the raised source/drain regions 50). The reaction during the anneal creates silicides 62, as shown in FIG. 9.

After forming the silicides 62 as illustrated in FIG. 9, portions of the metal layer 58 that did not react to form a silicide (unreacted (noble) metal regions) are removed. Any processed discussed herein, can be used to remove the unreacted metal regions, as illustrated in FIG. 9.

In another embodiment, a wafer cassette can be spun about its center axis in a closed chamber. The superoxidizer is introduced into the wafer cassette. The speed of the cassette rotation will create a thin boundary layer of the superoxidizer solution to form over the semiconductor wafer or wafers in the wafer cassette. While the superoxider is flowing, the gas including chlorine is introduced into the chamber's ambient. Once introduced into the chamber's ambient, the gas including chlorine can move across the thin boundary layer over the semiconductor wafer or wafers. Since the thin boundary layer is very permeable to the gas including chlorine, a lower concentration of the gas including chlorine may be used in this embodiment as opposed to other embodiments described.

Various methods for mixing a gas including chlorine with a superoxidizer, that may include an oxidizer and an oxidizing acid, are discussed. Any order or combination used to mix the chemicals for any of the spray tools can be used in an immersion process and vice versa.

As described above, in one embodiment a gas including chlorine is introduced into an oxidizer chemistry to form a chlorine-rich chemistry. In one embodiment, the oxidizer chemistry is H₂O₂ and the dissolved gas including chlorine is HCl. The mixture of the HCl gas and H₂O₂, in one embodiment, is combined with H₂SO₄ to form a chlorine-rich superoxidizer (e.g., a chlorine-rich Piranha).

If the chlorine-rich superoxidizer is chlorine-rich Piranha, the chlorine rich Piranha has a high ratio of H₂SO₄ to H₂O₂ (e.g., 7:1). By diluting the H₂O₂ in the Piranha, the exothermic reaction of Piranha is desirably decreased so that the chlorine is not undesirably evolved out of the chlorine-rich Piranha. A high amount of chlorine is preferred to effectively etch noble metals. In the processes described, the noble metal is oxidized and a metal salt is formed. For example, Pt⁰ can be oxidized to Pt^{+2,3, or 6} by the superoxidizer. The gas including chlorine forms a metal salt with the oxidized Pt metal.

The overall simplified reaction when Piranha with a gas including chlorine is used to etch Pt could be the following, which shows a copious amount of chloride ions mixed with an aqueous solution of an oxidizer.
Pt⁴⁺(aq)+6Cl⁽⁻⁾(aq)+2H⁺(aq)<−>H₂PtCl₆ (aq)

This chemistry dissolves platinum due both to the oxidizing power of the superoxidizer (e.g., Piranha) and the ability of a chloride ion to form a highly stable, partially covalent polyatomic ions with the metal ions once they are oxidized. By removing the free metal ions from solution, the formation of the chloride containing polyatomic ions allows the oxidations reaction to continue toward equilibrium. This same mechanism occurs when other metals, such as noble metals, transition metals, lanthanides, actinides and their respective alloys are used.

Thus, in one embodiment HCl is continuously introduced into Piranha. (Piranha may also be referred to as hot Piranha because after chemistries are combined to form Piranha an exothermic reaction occurs bringing the temperature up to approximately 90 to 110 degrees Celsius. In addition, the Piranha may be heated beyond this temperature range). The combination is a metal removal chemistry, which in one embodiment is a noble metal removal chemistry. The metal removal chemistry is a strong oxidizing/complexing mixture capable of dissolving metals, such as noble metal, rare earths, lanthanides, transition metals, actinides, and their alloys.

A gas including chlorine (e.g., HCl (in gas form) is used instead of an aqueous chemistry including chlorine (e.g. HCl (in liquid form) combined with water), as in Aqua Regia. Introducing a gas including chlorine into a superoxidizer, such as Piranha, is desirable over using an aqueous chemistry including chlorine. For example, mixing aqueous HCl (e.g., 35 volume % HCl/65 volume % H₂O) into Piranha causes a violent and uncontrollable reaction because adding the aqueous HCl is like adding water to a hot acid. In addition, the chlorine is out-gassed form the solution so a steady supply to maintain a steady state concentration is undesirably needed. In addition, the more aqueous HCl that is added to the solution, the more dilute the overall solution becomes. Furthermore, aqueous HCl creates an exothermic reaction thus, undesirably increasing the bath temperature. It may be difficult then to control the bath temperature.

As discussed above the process can use an immersion tool, spray tool, or another suitable tool. Immersion tools (also referred to as a wet bench) are usually limited to removing only one type of metal to prevent cross-contamination. In addition, immersion tools take up more floor space than spray tools. Therefore, it may be desirable to implement the above processes using a spray tool instead of an immersion tool.

As should be appreciated, the chlorine is available concurrently with the process chemistry to etch a metal on a workpiece. The etch desirably can be formed in one-step. In addition, the above processes increase tool capacity because the above processes allow immersion or spray tools to etch hard to etch materials, such as platinum and other noble materials, which cannot be done with these conventional tool setups using conventional chemistries.

In one embodiment, a method for etching a metal on a workpiece includes producing a process chemistry of copious chloride superoxidizer mixture with use of a gas containing chlorine, wherein producing the process chemistry of copious chloride superoxidizer mixture comprises combining the gas containing chlorine with an superoxidizer at a rate capable of producing copious free chloride ions in solution, wherein the rate of introducing the gas containing chlorine is a continuous rate, a periodic rate, or a combination of continuous and periodic rate; exposing the workpiece to the presence of the process chemistry of copious chloride superoxidizer mixture; and replenishing a component of the oxidizer or the copious chloride superoxidizer mixture at a continuous rate, a periodic rate, or a combination of continuous and periodic rates.

By now it should be appreciated that there has been provided a method for etching a metal that is safe (with safeguards in place), robust and cost effective. The proposed processes and chemistries do not aggressively etch metals or roughen the surface of the semiconductor device like Aqua Regia. Furthermore, the proposed processes and chemistries do not have very short process bath lives like Aqua Regia (approximately 6-7 hours).

In the foregoing specification, the invention has been described with reference to specific embodiments. However, one of ordinary skill in the art appreciates that various modifications and changes can be made without departing from the scope of the present invention as set forth in the claims below. Although the processes described above are discussed in regards to removing noble metals, the processes can also be used to remove titanium nitride, rare earths, lanthanides, actinides, transition metals and the like. In addition, although the problem being discussed focuses on removing metals after silicidation, or more specifically removing unreacted metals after silicidation, the process and tools described can be used at any point in manufacturing when metals are removed, such as decontaminating a semiconductor process tool. Accordingly, the specification and figures are to be regarded in an illustrative rather than a restrictive sense, and all such modifications are intended to be included within the scope of the present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. The terms “a” or “an”, as used herein, are defined as one or more than one. Moreover, the terms “front”, “back”, “top”, “bottom”, “over”, “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein. The term “coupled”, as used herein, is defined as connected, although not necessarily directly, and not necessarily mechanically.

1. A method for removing a noble metal over a semiconductor workpiece comprising:
forming a layer including a noble metal over the semiconductor workpiece including a semiconductor material;
reacting a first portion of the layer including the noble metal with the semiconductor material after forming the layer including the noble metal over the semiconductor workpiece;
producing a process chemistry of copious chloride superoxidizer with use of a gas containing chlorine; and
exposing the semiconductor workpiece to the process chemistry of the copious chloride superoxidizer to remove an unreacted portion of the noble metal.

2. The method of claim 1, wherein producing the process chemistry comprises coupling a superoxidizer with a supply of the gas containing chlorine.

3. The method of claim 2, wherein coupling includes one selected from the group consisting of introducing the gas containing chlorine into the superoxidizer, and bubbling the gas containing chlorine into the superoxidizer.

4. The method of claim 2, wherein the superoxidizer comprises one or more selected from the group consisting of peroxide, ozone, peroxymonosulfuric acid, a nitric acid, and sulfuric acid.

5. The method of claim 1, wherein producing the process chemistry of copious chloride superoxidizer comprises combining the gas containing chlorine with an superoxidizer at a rate capable of producing copious free chloride ions in solution in a presence of the superoxidizer.

6. The method of claim 5, wherein combining the gas containing chlorine with the superoxidizer further comprises solubilizing the gas containing chlorine into the superoxidizer.

7. The method of claim 6, wherein solubilizing the gas containing chlorine comprises bubbling the gas containing chlorine into the superoxidizer.

8. The method of claim 5, wherein combining the gas containing chlorine with the superoxidizer further comprises introducing the gas containing chlorine with the superoxidizer using one selected from the group consisting of a contactor, a semi-permeable membrane, and a mixer.

9. The method of claim 1, wherein the noble metal is resistant to at least one selected from the group consisting of corrosion and oxidation.

10. The method of claim 1, wherein the noble metal includes one selected from the group consisting of platinum (Pt), gold (Au), silver (Ag), palladium (Pd), copper (Cu), ruthenium (Ru), iridium (Ir), and respective alloys.

11. The method of claim 1, wherein exposing comprises immersing the workpiece within a bath of the process chemistry of copious chloride superoxidizer.

12. The method of claim 1, wherein exposing comprises spraying the process chemistry of copious chloride superoxidizer onto the semiconductor workpiece.

13. A method of removing a noble metal comprising:
forming a layer including a noble metal over a semiconductor workpiece including a semiconductor material;
reacting a first portion of the layer including the noble metal with and the semiconductor material after forming the layer including the noble metal over the semiconductor workpiece;
forming a noble metal removal chemistry wherein forming the noble metal removal chemistry comprises mixing a superoxidizer with a gas containing chlorine and wherein the noble metal removal chemistry comprises a chlorine-rich superoxidizer; and
exposing an unreacted portion of the noble metal to the noble metal removal chemistry after forming the noble metal removal chemistry.

14. (canceled)

15. The method of 13, wherein forming the noble metal removal chemistry further comprises forming the superoxidizer by mixing an oxidizing acid with an oxidizer.

16. The method of 13, further comprising:
forming the noble metal removal chemistry prior to exposing at least the portion of the noble metal, wherein forming the noble metal removal chemistry comprises mixing an oxidizer with a gas containing chlorine.

17. The method of claim 16, wherein:
mixing an oxidizer with a gas containing chlorine forms a chlorine-rich oxidizer; and forming the noble metal removal chemistry further comprises mixing the chlorine-rich oxidizer with an oxidizing acid to form a chlorine-rich superoxidizer.

18. The method of claim 13, further comprising forming the noble metal removing chemistry prior to exposing at least the portion of the noble metal, wherein forming the noble metal removing chemistry comprises mixing hydrochloric acid in gas form, hydrogen peroxide, and sulfuric acid.

19-20. (canceled)

21. A method of removing a noble metal comprising:
forming a layer including a noble metal over a semiconductor workpiece including a semiconductor material;
reacting a first portion of the layer including the noble metal with the semiconductor material, after forming the layer including the noble metal over the semiconductor workpiece; and
producing a process chemistry of a superoxidizer comprising chlorine with use of a gas comprising chlorine; and
exposing the semiconductor workpiece to the process chemistry of the superoxidizer to remove an unreacted portion of the noble metal.
